(19) United States
(12) Patent Application Publication
(10) Pub. No.: US 2024/0353270 A1
(43) Pub. Date: Oct. 24, 2024

(54) TEMPERATURE MEASURING DEVICE

(71) Applicant: Fujikura Ltd., Tokyo (JP)

(72) Inventors: Randeep Singh, Tokyo (JP); Akihiro Takamiya, Tokyo (JP); Yoji Kawahara, Tokyo (JP); Tsuyoshi Ogawa, Tokyo (JP); Hiromichi Tanaka, Tokyo (JP)

(73) Assignee: Fujikura Ltd., Tokyo (JP)

(21) Appl. No.: 18/682,727

(22) PCT Filed: Mar. 22, 2022
(86) PCT No.: PCT/JP2022/013087

§ 371 Date: Feb. 9, 2024

(30) Foreign Application Priority Data
Aug. 18, 2021 (JP) 2021-133131

(51) Int. Cl. G01K 13/02; G01K 1/14; H01M 10/613; H01M 10/6569

(52) U.S. Cl. CPC G01K 13/026; G01K 1/14; H01M 10/613; H01M 10/6569

(57) ABSTRACT

A temperature measuring device includes a heat pipe having a container in which a working fluid is enclosed, a temperature sensor that detects a temperature of the heat pipe, and a wire portion connected to the temperature sensor, in which the heat pipe receives heat from a plurality of heat sources.

### CROSS-REFERENCE TO RELATED APPLICATIONS

The present application claims priority to Japanese Patent Application No. 2021-133131, filed Aug. 18, 2021. The contents of this application are incorporated herein by reference in their entirety.

### BACKGROUND

### Technical Field

The present invention relates to a temperature measuring device.

### Description of the Related Art

In the related art, a temperature measuring device as disclosed in Patent Document 1 has been known. The temperature measuring device has a plurality of temperature sensors for measuring temperatures of a plurality of arranged heat sources (battery cells). Abnormalities are detected based on the temperature change of the battery by measuring the temperatures of the plurality of battery cells.

### Patent Document

Patent Document 1: United States Patent Publication No. 2010/0136392

In the configuration of Patent Document 1, a plurality of temperature sensors are disposed in accordance with the number of heat sources. In addition, since circuits for outputting the measurement data are connected to each of the plurality of temperature sensors, the temperature measuring device may become large in size.

### SUMMARY

One or more embodiments provide a temperature measuring device capable of measuring temperature changes of a plurality of heat sources with one temperature sensor.

A temperature measuring device according to one or more embodiments includes a heat pipe having a container in which a working fluid is enclosed (a container that contains a working fluid), a temperature sensor that detects a temperature of the heat pipe, and a wire portion (example of the claimed wire) connected to the temperature sensor, in which the heat pipe receives heat from a plurality of heat sources.

In this configuration, by thermally connecting the heat pipe to the plurality of heat sources, circulation of the working fluid occurs, and the heat generated from the heat source can be transferred to the vicinity of the temperature sensor by the working fluid. For example, in a case where the temperature of any one heat source of the plurality of heat sources rises, the temperature of the heat pipe detected by the temperature sensor also rises. Therefore, it is possible to detect that an abnormality has occurred in any one of the plurality of heat sources which is in contact with the heat pipe. In this way, one temperature sensor can detect abnormalities in the plurality of heat sources, so that the temperature measuring device can be downsized.

In addition, in the temperature measuring device described above, the heat transfer between the heat source and the temperature sensor is performed by the working fluid. For example, in a case of simply conducting heat through a rod with a highly thermally conductive metal, the transfer of the heat may take several minutes. On the other hand, since heat transfer through the working fluid as described above is significantly faster than the heat transfer speed through heat conduction, the response speed to the temperature change of the heat source can be increased.

From the above, according to the temperature measuring device of the above-described aspect, it is possible to quickly detect abnormalities in the plurality of heat sources with a simple configuration.

In addition, the temperature measuring device may further include an interface spreader plate located between the plurality of heat sources and the heat pipe, in which the heat pipe may have a flat shape, and the interface spreader plate may have a plate shape extending to be orthogonal to a thickness direction of the heat pipe.

In addition, the temperature measuring device may further include an insulating layer located between the plurality of heat sources and the heat pipe, in which the heat pipe may have a flat shape, and the insulating layer may have a plate shape extending to be orthogonal to a thickness direction of the heat pipe.

In addition, the temperature measuring device may further include a height adjustment layer located between the plurality of heat sources and the heat pipe, in which the heat pipe may have a flat shape, and the height adjustment layer may have a plate shape extending to be orthogonal to a thickness direction of the heat pipe.

In addition, the wire portion may be an FPC.

In addition, the temperature sensor may be disposed at a first end portion in a longitudinal direction of the heat pipe, and a side closer to the first end portion of the heat pipe may be a condensation portion where vapor of the working fluid condenses.

In addition, the temperature measuring device may further include a heat sink disposed at a second end portion in a longitudinal direction of the heat pipe.

In addition, the temperature measuring device may further include a cold plate having an inlet and an outlet for a coolant, in which the plurality of heat sources may be disposed between the cold plate and the heat pipe.

According to one or more embodiments, it is possible to provide a temperature measuring device capable of measuring temperature changes of a plurality of heat sources with one temperature sensor.

### BRIEF DESCRIPTION OF THE DRAWINGS

FIG. 1 is a top view of a temperature measuring device according to a first example.

FIG. 2 is a side view of the temperature measuring device according to the first example.

FIG. 3 is a cross-sectional view of a heat pipe.

FIG. 4 is a top view of a temperature measuring device according to a second example.

FIG. 5 is a side view of the temperature measuring device according to the second example.

FIG. 6 is a top view of a temperature measuring device according to a third example.

FIG. 7 is a side view of the temperature measuring device according to the third example.

### DESCRIPTION OF THE EMBODIMENTS

### First Example

Hereinafter, a configuration of a temperature measuring device 1 according to one or more embodiments will be described with reference to the drawings.

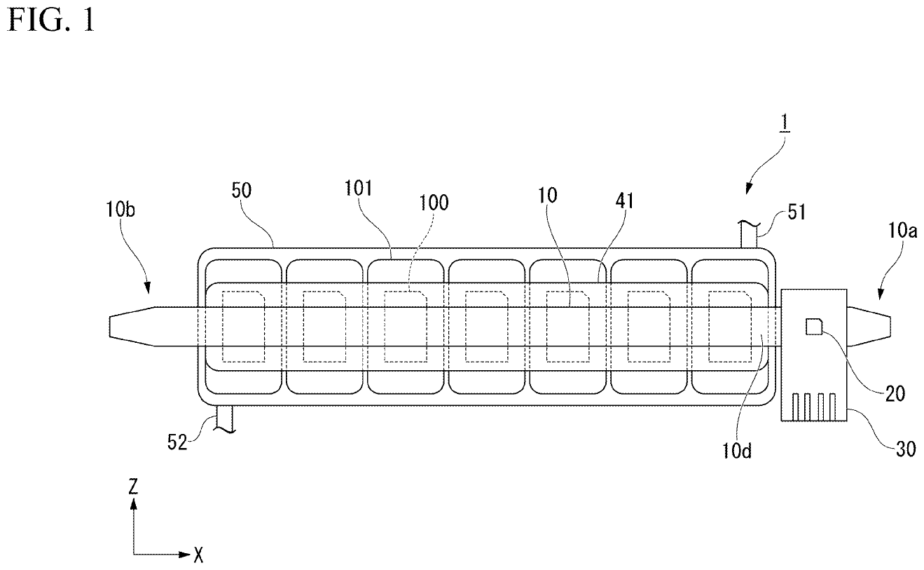

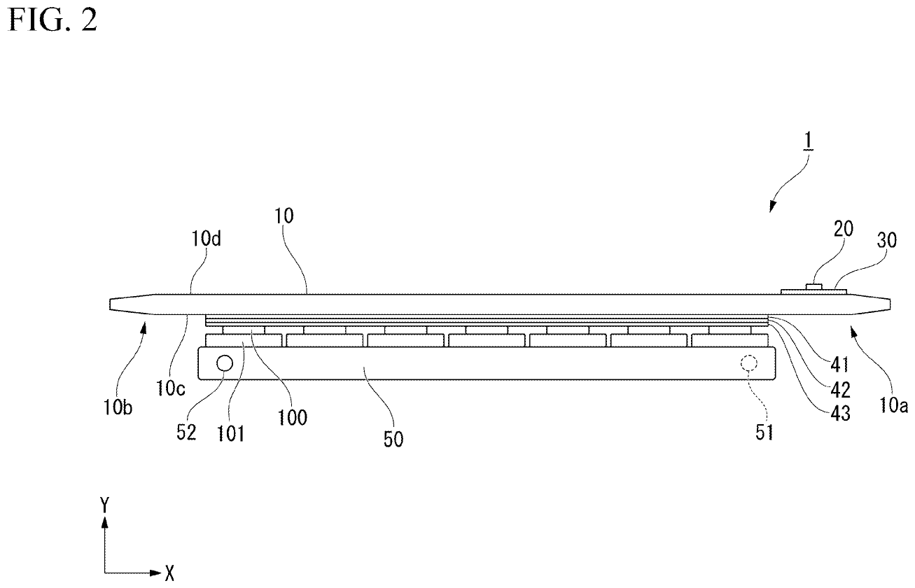

As shown in FIG. 1 and FIG. 2, the temperature measuring device 1 includes a heat pipe 10, a temperature sensor 20, a wire portion 30, an interface spreader plate 41, an insulating layer 42, and a height adjustment layer 43. The heat pipe 10 has a flat shape in a cross-sectional view orthogonal to a longitudinal direction of the heat pipe 10. The temperature measuring device 1 measures temperatures of a plurality of heat sources 100.

Each heat source 100 is disposed between the heat pipe 10 and a cold plate 50. The heat source 100 is, for example, a plurality of semiconductors mounted on a substrate 101. In FIG. 1, one heat source 100 is mounted on one substrate 101. It should be noted that the plurality of heat sources 100 may be mounted on one substrate 101.

### Definition of Direction

Here, in one or more embodiments, an XYZ orthogonal coordinate system is set, and a positional relationship of each configuration will be described. An X direction is a longitudinal direction in which the heat pipe 10 extends. A Y direction is a thickness direction of the heat pipe 10. A direction orthogonal to both the X direction and the Y direction is defined as a Z direction. In the following, the X direction is referred to as the longitudinal direction, the Y direction is referred to as the thickness direction, and the Z direction is referred to as the width direction.

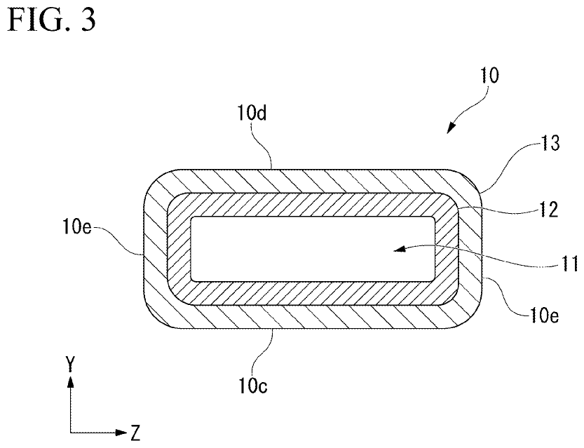

As shown in FIG. 3, the heat pipe 10 includes a wick 12 and a container 13. The heat pipe 10 is a heat transfer element that receives heat from the plurality of heat sources 100 and that transfers the heat by using latent heat of a working fluid enclosed in the container 13.

As shown in FIG. 3, the heat pipe 10 has a first surface 10c and a second surface 10d facing in the thickness direction and two side surfaces 10e facing in the width direction.

The container 13 is a hollow container formed in a flat shape in a cross-sectional view orthogonal to the longitudinal direction. The material of the container 13 may be appropriately selected depending on conditions such as a type of the working fluid and the operating temperature. For example, the container 13 is formed of a metal such as copper, steel, or aluminum. In particular, in a case of using a metal material having high thermal conductivity such as copper or aluminum, it is possible to enhance the heat transportability or heat diffusivity. In one or more embodiments, a copper tube is used as the container 13.

The width of the container 13 in the width direction is larger than the thickness in the thickness direction. That is, a surface area of the first surface 10c is larger than a surface area of the side surface 10e. A length of the heat pipe 10 in the longitudinal direction is set to be the length that the heat pipe 10 is able to be in contact with the plurality of heat sources 100. In the width direction, the width of the heat pipe 10 may be smaller than the width of the heat source 100.

In the longitudinal direction, the width of the heat pipe 10 in the width direction is substantially constant. In addition, in the longitudinal direction, the thickness of the heat pipe 10 in the thickness direction is substantially constant. At an end portion of the heat pipe 10 in the longitudinal direction, the width in the width direction and the thickness in the thickness direction of the heat pipe 10 may be gradually narrowed toward an end surface.

The working fluid is enclosed in an internal space 11 of the container 13. The working fluid is a well-known heat transfer medium capable of undergoing a phase change, and undergoes the phase change between a liquid phase and a gas phase in the container 13. As the working fluid, for example, water, alcohol, ammonia, chlorofluorocarbon substitutes, and the like can be adopted. The type of the working fluid may be appropriately changed depending on a temperature measurement range or accuracy required for the temperature measuring device 1. In the present specification, in some cases, the working fluid in the liquid phase is referred to as “working liquid”, and the working fluid in the gas phase is referred to as “vapor”. In addition, in a case where the liquid phase and the gas phase are not particularly distinguished, the working fluid is simply referred to as the working fluid. The working fluid is not shown in FIG. 3.

The wick 12 is disposed in the container 13.

The wick 12 is formed along an inner peripheral surface of the container 13 as shown in FIG. 3, for example. The wick 12 extends over its entire length inside the container 13 in the longitudinal direction. The wick 12 may be formed only in a partial region in a circumferential direction and the longitudinal direction on the inner peripheral surface of the container 13.

The wick 12 is formed by bundling a plurality of thin metal wires, for example. The thin metal wire is a linear body extending in the longitudinal direction of the container 13. The thin metal wire of the wick 12 is, for example, a plurality of thin copper wires. An outer diameter of the thin copper wire is, for example, several μm to several hundred μm.

A gap extending in the longitudinal direction is formed between the thin copper wires. The gap is used as a liquid flow path for the working liquid to flow, and serves as a reflux path (hereinafter, referred to as a “flow path”) for the working liquid to reflux from a condensation portion to an evaporation portion. The working liquid in the flow path flows in the longitudinal direction due to capillary force.

The wick 12 is not limited to the thin metal wire, and a metal mesh (net-like body), a sintered body of a metal powder, and the like may also be used.

Exemplary examples of the metal forming the wick 12 include copper, aluminum, stainless steel, and alloys thereof. The wick 12 is not limited to being formed of metal, and may be formed of a carbon material and the like. For example, the wick 12 may be formed of a thin carbon wire, a carbon mesh, and the like.

The interface spreader plate 41 is located between the plurality of heat sources 100 and the heat pipe 10. The interface spreader plate 41 has a plate shape and extends to be orthogonal to the thickness direction. The interface spreader plate 41 is formed of a highly thermally conductive metal, and is formed of, for example, a metal having excellent thermal conductivity such as copper, a copper alloy, aluminum, or an aluminum alloy.

The interface spreader plate 41 is configured to cover the plurality of heat sources 100 when viewed from the thickness direction. A dimension of the interface spreader plate 41 in the width direction is larger than the width of the heat pipe 10, and is equal to or larger than the width of the heat source 100.

In the example of FIG. 1, although one interface spreader plate 41 is disposed so as to cover seven heat sources 100, the number of the interface spreader plates 41 can be changed as appropriate. For example, two interface spreader plates 41 may be disposed, one interface spreader plate 41 may cover three heat sources 100, and the other interface spreader plate 41 may cover remaining four heat sources 100. The number of heat sources 100 may be changed as appropriate.

When the interface spreader plate 41 having a wide surface area comes into contact with the first surface 10c of the heat pipe 10, heat generated by the plurality of heat sources 100 can be efficiently transferred to the heat pipe 10.

The interface spreader plate 41 may be omitted.

The insulating layer 42 is located between the plurality of heat sources 100 and the heat pipe 10. The insulating layer 42 has a plate shape and extends to be orthogonal to the thickness direction. In the examples of FIG. 1 and FIG. 2, the insulating layer 42 is located between the interface spreader plate 41 and the plurality of heat sources 100. Even in a case where an electric circuit is formed on a surface of the heat source 100 or in a case where an electric leakage occurs in the heat source 100, the presence of the insulating layer 42 can prevent an electrical short circuit through the heat pipe 10 or the interface spreader plate 41.

The insulating layer 42 has the same size as the interface spreader plate 41 when viewed from the thickness direction. Each of a plurality of the insulating layers 42 may be disposed so as to cover each of the plurality of heat sources 100 such that the plurality of heat sources 100 and the heat pipe 10 are not electrically connected.

The insulating layer 42 is preferably formed of a material having the insulating property and having the low thermal resistance. In this case, the heat generated in the heat source 100 can be efficiently transferred to the heat pipe 10.

In a case where the heat pipe 10 is covered with an insulating coating or a case where the interface spreader plate 41 has the insulating property, the insulating layer 42 may not be disposed.

The height adjustment layer 43 is located between the plurality of heat sources 100 and the heat pipe 10. The height adjustment layer 43 has a plate shape and extends so as to be orthogonal to the thickness direction. In the example of FIG. 1 and FIG. 2, the height adjustment layer 43 is located between the insulating layer 42 and the plurality of heat sources 100.

The height adjustment layer 43 is a layer formed of a material that deforms under compression. For example, in a case where there is a variation in positions of the upper surfaces of the plurality of heat sources 100 in the thickness direction, the height adjustment layer 43 is pressed against the plurality of heat sources 100 and deformed according to the positions of the heat sources 100 in the thickness direction, thereby preventing a gap (layer of air) from occurring between the upper surface of the heat source 100 and the heat pipe 10. Accordingly, the heat from the plurality of heat sources 100 can be efficiently transferred to the heat pipe 10.

The height adjustment layer 43 has the same size as the interface spreader plate 41 when viewed from the thickness direction. A plurality of the height adjustment layers 43 may be disposed so as to individually cover the heat source 100. Accordingly, the electrical short circuit between the heat sources 100 via the height adjustment layers 43 can be prevented.

The height adjustment layer 43 is preferably formed of a material that is deformable under compression and has low thermal resistance. In this case, the heat generated in the heat source 100 can be efficiently transferred to the heat pipe 10. For example, the height adjustment layer 43 may be formed of silicone. The height adjustment layer 43 may be omitted. For example, in a case where the positions of the upper surfaces of the plurality of heat sources 100 are equivalent or a case where the heat pipe 10 is easily deformable in the thickness direction, the plurality of heat sources 100 can be brought into direct contact with the heat pipe 10.

In addition, the order in which the interface spreader plate 41, the insulating layer 42, and the height adjustment layer 43 are laminated in the thickness direction is not limited to this order and may be changed. Furthermore, instead of disposing the insulating layer 42 and the height adjustment layer 43, a layer formed of a material having both the insulating property and a height adjustment function may be disposed. In this way, a plurality of functions may be imparted to one layer.

The temperature sensor 20 and the wire portion 30 are disposed on a side closer to a first end portion 10a of the heat pipe 10 in the longitudinal direction.

The temperature sensor 20 detects a temperature of the heat pipe 10 at a location where the temperature sensor 20 is disposed. A thermistor or a thermocouple may be used as the temperature sensor 20. A thermistor is an electronic component whose resistance value changes due to temperature changes. The thermocouple is a temperature sensor composed of two different metal conductors. The temperature information detected by the temperature sensor 20 is transferred through the wire portion 30 as an electric signal and is input to a determination unit and a recording unit (not shown).

The temperature sensor 20 is disposed at a position different from that of the heat source 100 in the longitudinal direction. In addition, the temperature sensor 20 is disposed on a second surface 10d of the heat pipe 10. That is, the temperature sensor 20 is disposed on the second surface 10d opposite to the first surface 10c where the heat source 100 is disposed. The temperature sensor 20 is disposed in a central portion of the heat pipe 10 in the width direction.

The temperature sensor 20 is disposed at a position different from that of the heat source 100 in the thickness direction and the longitudinal direction. In this way, the temperature sensor 20 is disposed at a position that is a certain distance away from the plurality of heat sources 100. Accordingly, as an influence on the temperature detected by the temperature sensor 20, the heat transferred from the whole of the plurality of heat sources 100 to the temperature sensor 20 via the working fluid in the container 13 dominates over the heat transferred from the specific heat source 100 to the temperature sensor 20 via the container 13 by heat conduction. Therefore, it is possible to more reliably detect the situation of the temperature changes of the plurality of heat sources 100 by using one temperature sensor 20. In addition, even in a case where the working liquid evaporates and the wick 12 becomes dry in a specific portion in the heat pipe 10, overheating of the temperature measurement part and failure of the temperature sensor 20 can be prevented.

The location where the temperature sensor 20 is disposed may be changed as appropriate. For example, the temperature sensor 20 may be disposed on the first surface 10c of the heat pipe 10 or may be disposed at the same position as the heat source 100 in the longitudinal direction. Also in these cases, in a case where the temperature of one of the plurality of heat sources 100 rises, the temperature detected by the temperature sensor 20 rises. Therefore, it is possible to detect that an abnormality has occurred in any of the plurality of heat sources 100.

The wire portion 30 is electrically connected to the temperature sensor 20. The wire portion 30 transmits temperature data measured by the temperature sensor 20 to the determination unit or the recording unit. The wire portion 30 may be a metal wire capable of transmitting the temperature data, or may be flexible printed circuits (FPCs) in which a circuit is formed on a polyimide film. In a case where the FPC is used as the wire portion 30, the temperature sensor 20 and the heat pipe 10 can be reliably thermally connected to each other by bringing the FPC on which the temperature sensor 20 is mounted into contact with the heat pipe 10. In addition, since the FPC is thin, the temperature measuring device 1 can have a compact dimension in the thickness direction.

The wire portion 30 is disposed near the temperature sensor 20 on the second surface 10d of the heat pipe 10. In the example of FIG. 1, the wire portion 30 is disposed between the heat pipe 10 and the temperature sensor 20.

The wire portion 30 adheres to the heat pipe 10 with an adhesive. The adhesive is preferably a material that can reliably adhere the container 13 and the wire portion 30 to each other even in a case where the heat pipe 10 is heated by the heat of the heat source 100 and that has low thermal resistance. The adhesive may be, for example, an epoxy adhesive.

The wire portion 30 and the temperature sensor 20 may be disposed so that the temperature sensor 20 is in contact with the heat pipe 10, or a configuration other than the wire portion 30 may be disposed between the temperature sensor 20 and the heat pipe 10. In addition, an FPC with a built-in temperature sensor 20 may be used.

The measurement data obtained by the temperature sensor 20 is output as the electric signal to the determination unit or the recording unit (not shown) via the wire portion 30. The determination unit determines whether the plurality of heat sources 100 operate normally based on the measurement data. The recording unit records the measurement data on a recording medium. The determination unit and the recording unit may be configured to output a determination result and the recorded data to a control unit (not shown) that controls the operation of the heat source 100. A CPU can be used as the control unit. The determination unit and the recording unit may be provided inside the control unit or may be provided outside the control unit.

The plurality of heat sources 100 are disposed between the temperature measuring device 1 and the cold plate 50. Exemplary examples of the heat source 100 include a semiconductor and an electrochemical device (such as a battery cell), but may also be another device that generates heat during an operation. In the examples of FIG. 1 and FIG. 2, the heat source 100 is a semiconductor mounted on the substrate 101.

The plurality of heat sources 100 are arranged along the longitudinal direction. The length of the heat pipe 10 or the dimension of the interface spreader plate 41 is changed as appropriate depending on the number of the plurality of heat sources 100, which are arranged, and the exposure area. In addition, the shapes of the heat pipe 10 and/or the interface spreader plate 41 may be changed depending on the arrangement of the plurality of heat sources 100 or the shape of the upper surface of the heat sources 100.

The cold plate 50 is disposed below the heat source 100 (on a side opposite to the heat pipe 10 in the thickness direction when viewed from the heat source 100). In the examples of FIG. 1 and FIG. 2, the cold plate 50 is disposed below the substrate 101 on which the heat source 100 is mounted. The cold plate 50 is formed in a plate shape extending in the longitudinal direction and the width direction. The cold plate 50 is formed of, for example, metal such as aluminum, and a flow path of a coolant is provided inside the cold plate 50.

The cold plate 50 has an inlet 51 and an outlet 52 for the coolant. The coolant flows into the cold plate 50 from the inlet 51 by using a pump or the like (not shown), passes through the flow path, and flows out from the outlet 52. By flowing the coolant through the flow path, the heat source 100 thermally connected to the cold plate 50 can be cooled.

### Temperature Measuring Method using Temperature Measuring Device 1

Next, an operation of the temperature measuring device 1 configured as described above will be described.

First, the heat generated by the heat source 100 is transferred to the heat pipe 10 via the height adjustment layer 43, the insulating layer 42, and the interface spreader plate 41. Because of this heat, the working liquid in the heat pipe 10 evaporates in the vicinity (high temperature portion) of the heat source 100. The vapor moves toward a low temperature portion away from the heat source 100 and condenses. In one or more embodiments, the low temperature portion is on a side of the first end portion 10a in which the temperature sensor 20 is disposed. The working liquid condensed in the low temperature portion moves along a flow path of the wick 12 and moves to the high temperature portion again.

In this way, when the working fluid circulates in the heat pipe 10, the heat from the heat source 100 is transferred to the vicinity of the temperature sensor 20 (heat transferring step). In addition, because of a pressure change that occurs in the internal space 11 when a phase change, from the working liquid to the vapor, or from the vapor to the working liquid, undergoes, the working fluid circulates over the entire internal space 11 without being locally stopped.

As the working fluid continues to circulate, the temperature distribution of the heat pipe 10 may become in an equilibrium state (a state in which the temperature distribution does not change). Hereinafter, the state in which the temperature distribution of the heat pipe 10 is in the equilibrium state is also referred to as a steady state.

Next, the temperature sensor 20 measures the temperature of the heat pipe 10 at a location where the temperature sensor 20 is disposed (temperature measuring step). For example, in the steady state, the temperature measured by the temperature sensor 20 is constant. The temperature data measured by the temperature sensor 20 is output to the determination unit via the wire portion 30.

Then, the determination step is performed. In the determination step, the determination unit determines whether or not each heat source 100 is operating normally based on the measurement data obtained from the temperature sensor 20. A determination result of the determination unit may be output to the control unit of the heat source 100.

Here, in a case where an abnormality has occurred in at least one of the plurality of heat sources 100, a change occurs in the temperature distribution of the heat pipe 10, and a temperature different from the temperature measured in a steady state is measured by the temperature sensor 20. For example, in a case where one heat source 100 among the plurality of heat sources 100 excessively generates heat, the temperature measured by the temperature sensor 20 rises. In addition, when the operation of one heat source 100 among the plurality of heat sources 100 is stopped and the heat generation is stopped, the temperature measured by the temperature sensor 20 decreases. Thus, it is possible to detect that an abnormality has occurred in any of the heat sources 100 based on the temperature change ΔT from the temperature in the steady state.

A threshold value for the temperature change ΔT may be stored in the determination unit, and in a case where a difference between the temperature in the steady state and the measured temperature exceeds the threshold value, it may be set to determine that an abnormality has occurred in the heat source 100. In addition, the abnormality may be determined based on data such as a tendency of the temperature change and a rate of temperature change. Furthermore, in a case where the determination unit determines that the abnormality has occurred, the operation of the heat source 100 may be stopped via the control unit of the heat source 100.

Here, a method of detecting an abnormality caused by the temperature of the battery cell in a case where the heat source 100 is the battery cell of the electric vehicle will be described.

It is assumed that 20 sets of modules each including 12 battery cells are disposed in the electric vehicle. In the related art, since one temperature sensor is disposed for one battery cell, it is necessary to install a total of 240 temperature sensors. Furthermore, it is necessary to wire the wire portions for outputting the measurement results of the 240 temperature sensors, which may cause the temperature measuring device to become large in size.

On the other hand, according to the temperature measuring device 1 of one or more embodiments, by thermally connecting one heat pipe 10 to 12 battery cells, the temperature changes of the 12 battery cells can be measured by one temperature sensor 20. That is, it is possible to detect abnormalities in a plurality of battery cells by disposing one temperature measuring device 1 for one set of modules. In this way, according to the temperature measuring device 1, it is possible to measure the temperature changes of the plurality of heat sources 100 with a simple configuration, and the wiring of the wire portion 30 can be simplified, so that the space can be saved.

In addition, only the module including the battery cell in which the abnormality has occurred may be controlled to release electrical connection from the electric vehicle. Accordingly, it is possible to enhance the safety of the electric vehicle.

As described above, the temperature measuring device 1 of one or more embodiments includes the heat pipe 10 having the container 13 in which the working fluid is enclosed, the temperature sensor 20 that detects the temperature of the heat pipe 10, and the wire portion 30 that is connected to the temperature sensor 20, and the heat pipe 10 receives heat from the plurality of heat sources 100.

In this configuration, by thermally connecting the heat pipe 10 to the plurality of heat sources 100, circulation of the working fluid occurs, and the heat generated from the heat source 100 can be transferred to the vicinity of the temperature sensor 20 by the working fluid. For example, in a case where the temperature of any one heat source 100 of the plurality of heat sources 100 rises, the temperature of the heat pipe 10 detected by the temperature sensor 20 also rises. Therefore, it is possible to detect that an abnormality has occurred in any one of the plurality of heat sources 100 which is in contact with the heat pipe 10. In this way, one temperature sensor 20 can detect abnormalities in the plurality of heat sources 100, so that the temperature measuring device 1 can be downsized.

In addition, in the temperature measuring device 1 of one or more embodiments, heat is transferred between the heat source 100 and the temperature sensor 20 by the working fluid. For example, in a case of simply conducting heat through a rod with a highly thermally conductive metal, the transfer of the heat may take several minutes. On the other hand, since heat transfer through the working fluid as in one or more embodiments is significantly faster than the heat transfer speed through heat conduction, the response speed to the temperature change of the heat source 100 can be increased.

From the above, according to the temperature measuring device 1 of the above-described aspect, it is possible to quickly detect abnormalities in the plurality of heat sources 100 with a simple configuration.

In addition, the temperature measuring device 1 may further include an interface spreader plate 41 located between the plurality of heat sources 100 and the heat pipe 10, and the heat pipe 10 may have a flat shape, and the interface spreader plate 41 may have a plate shape extending to be orthogonal to the thickness direction of the heat pipe 10.

Accordingly, the heat generated by the plurality of heat sources 100 can be efficiently transferred into the heat pipe 10.

In addition, the temperature measuring device 1 may further include the insulating layer 42 located between the plurality of heat sources 100 and the heat pipe 10, and the heat pipe 10 may have a flat shape, and the insulating layer 42 may have a plate shape extending to be orthogonal to the thickness direction of the heat pipe 10.

Accordingly, an electrical short circuit via the heat pipe 10 or the interface spreader plate 41 can be prevented.

In addition, the temperature measuring device 1 may further include the height adjustment layer 43 located between the plurality of heat sources 100 and the heat pipe 10, and the heat pipe 10 may have a flat shape, and the height adjustment layer 43 may have a plate shape extending to be orthogonal to the thickness direction of the heat pipe 10.

The heat from the plurality of heat sources 100 can be efficiently transferred to the heat pipe 10 by preventing a gap (layer of air) from being formed between the upper surface of the heat source 100 and the heat pipe 10.

In addition, the wire portion 30 may be an FPC.

Accordingly, the temperature measuring device 1 can be further downsized. In particular, since the heat pipe 10 is configured such that the thickness in the thickness direction is thinner than the dimension in the width direction, in a case of being combined with the FPC, it is possible to obtain a temperature measuring device 1 having a thin thickness in the thickness direction.

In addition, the temperature sensor 20 may be disposed at the first end portion 10a in the longitudinal direction of the heat pipe 10, and a side closer to the first end portion 10a of the heat pipe 10 may be a condensation portion where vapor of the working fluid condenses.

Accordingly, the heat of the heat source 100 can be efficiently transferred to the vicinity of the temperature sensor 20.

### Second Example

Next, a second example according to one or more embodiments will be described, but the basic configuration is the same as the configuration of the first example. Therefore, the same reference sign is given to the same configuration, the description thereof will be omitted, and only the difference will be described.

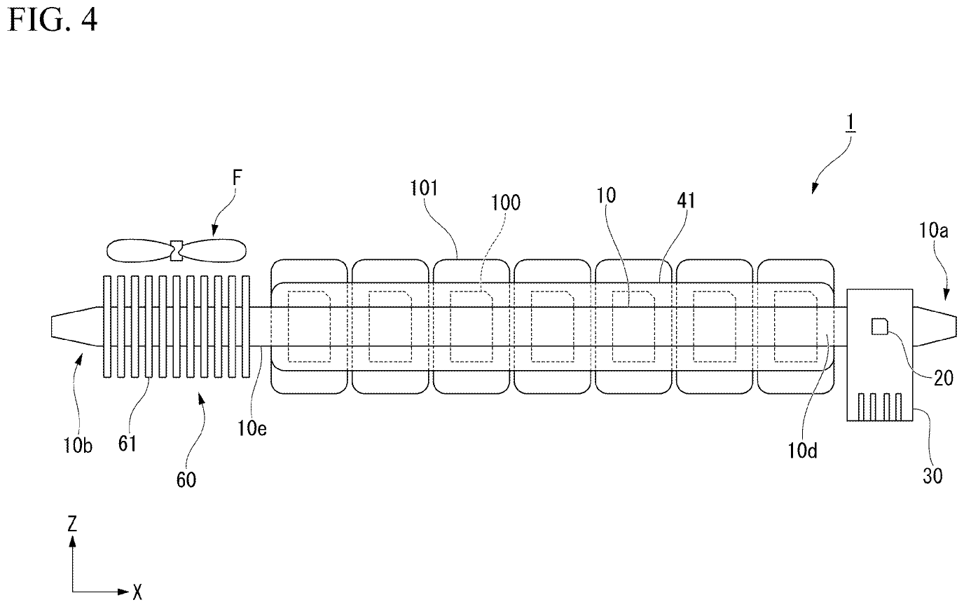

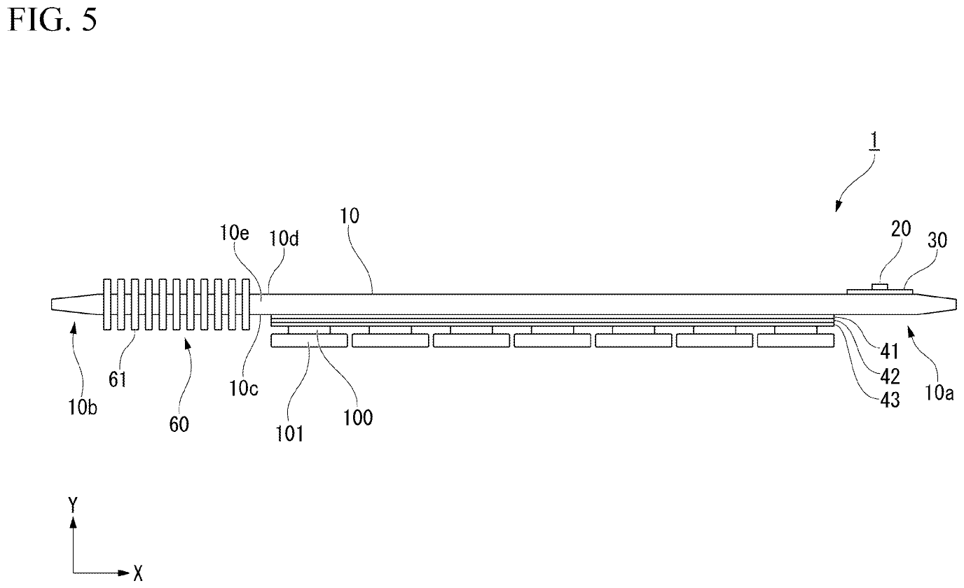

FIG. 4 and FIG. 5 show a temperature measuring device 1 according to the second example. The temperature measuring device 1 in the second example is different from the temperature measuring device 1 of the first example in that a heat sink 60 is formed in the second end portion 10b in the longitudinal direction of the heat pipe 10. The cold plate 50 is not disposed because the heat source 100 can be cooled by the heat pipe 10 formed with the heat sink 60.

The heat sink 60 has plate-shaped fins 61 that perpendicularly stand with respect to an outer peripheral surface of the container 13 of the heat pipe 10. The plurality of fins 61 are formed so as to be in contact with the first surface 10c, the second surface 10d, and the side surfaces 10e of the heat pipe 10 on the second end portion 10b. The fin 61 is formed of, for example, a metal having excellent thermal conductivity such as copper, a copper alloy, aluminum, or an aluminum alloy.

In the first example, the first end portion 10a is the condensation portion, but in the second example, a side closer to the second end portion 10b on which the heat sink 60 is disposed is the condensation portion. Hereinafter, the heat transfer and the circulation of the working fluid in the heat pipe 10 in one or more embodiments will be described.

The working liquid in the heat pipe 10 evaporates in the vicinity of the heat source 100 because of the heat of the heat source 100. The vapor moves to the side closer to the second end portion 10b of the heat pipe 10 provided with the heat sink 60 and condenses. At this time, the heat is transferred to the heat sink 60. The heat transferred to the fin 61 having a large surface area is efficiently dissipated from the fin 61. Furthermore, the heat may be dissipated from the fin 61 more efficiently by blowing the air from a fan F. In this way, the heat source 100 can be cooled by the heat sink 60.

The working liquid condensed on the second end portion 10b moves to the vicinity of the heat source 100 along the flow path of the wick 12, and becomes vapor again. In this way, the working fluid mainly circulates from the heat source 100 to the second end portion 10b in the longitudinal direction. Furthermore, a circulation of the working fluid throughout the inside of the heat pipe 10, including the first end portion 10a, caused by the main circulation occurs, and a circulation of the working fluid caused by the temperature difference between the heat source 100 and the first end portion 10a occurs, as well. Due to the circulations of the working fluid, the temperature on the first end portion 10a also changes depending on the degree of heat generation of the heat source 100, so that the temperature change of the heat source 100 can be detected by the temperature sensor 20 disposed on the first end portion 10a.

As described above, the temperature measuring device 1 of one or more embodiments further includes the heat sink 60 disposed at the second end portion 10b in the longitudinal direction of the heat pipe 10.

Accordingly, it is possible to efficiently cool the plurality of heat sources 100 by using the heat pipe 10 while measuring the temperatures of the plurality of heat sources 100 by using one temperature sensor 20. In addition, since it is not necessary to install another cooling device for the heat source, the device having the heat source 100 can be downsized.

### Third Example

Next, a third example according to one or more embodiments will be described, but the basic configuration is the same as the configuration of the first example. Therefore, the same reference sign is given to the same configuration, the description thereof will be omitted, and only the difference will be described.

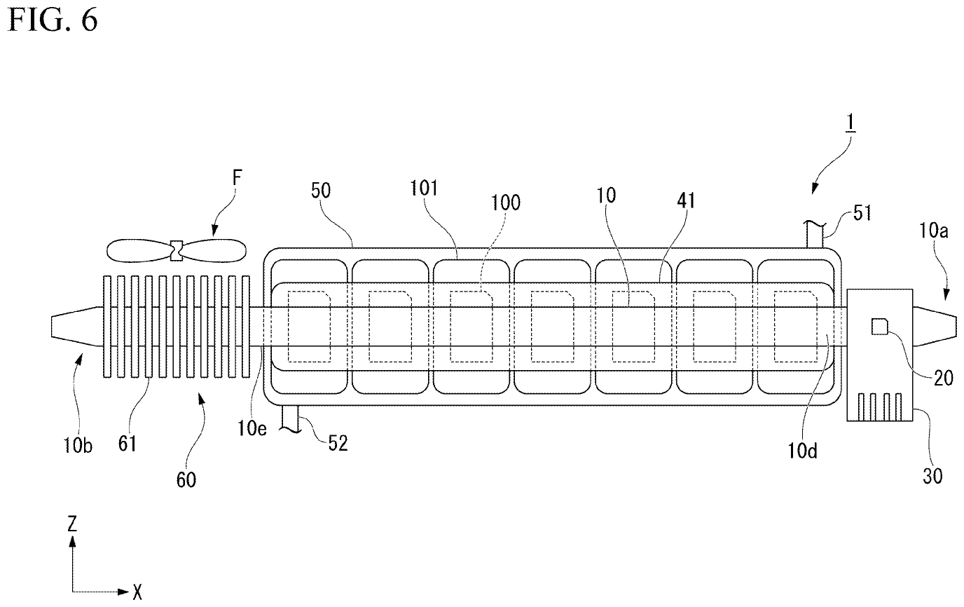

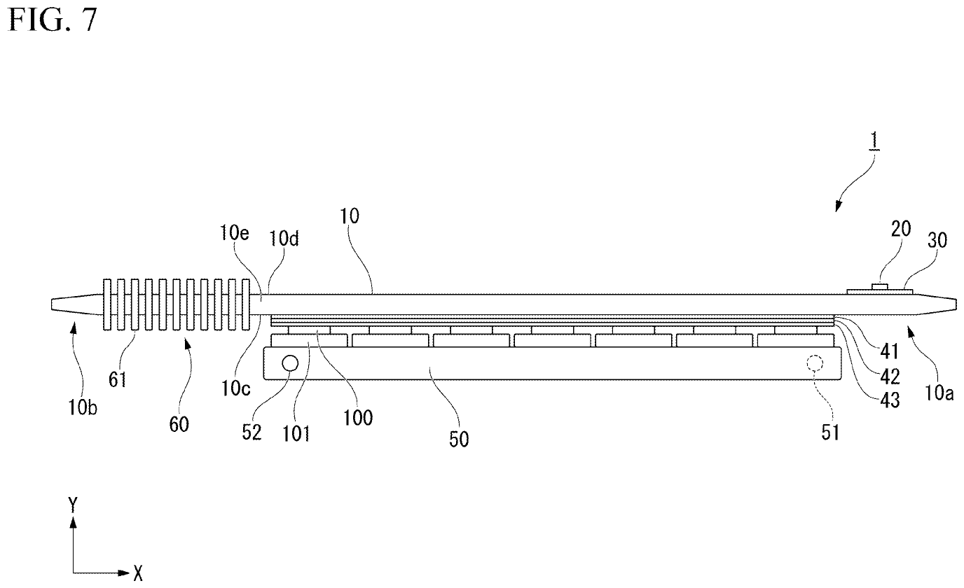

FIG. 6 and FIG. 7 show a temperature measuring device 1 according to the third example. In the third example, the heat sink 60 is formed in the second end portion 10b of the heat pipe 10 of the temperature measuring device 1 as in the second example. Although the cold plate 50 is not disposed in the second example, in the third example, the cold plate 50 is disposed below the heat source 100, and the heat source 100 is cooled by using the heat pipe 10 including the heat sink 60 and the cold plate 50.

As in the second example, due to the circulation of the working fluid inside the heat pipe 10, the temperature on the first end portion 10a also changes depending on the degree of heat generation of the heat source 100, so that the temperature change of the heat source 100 can be detected by the temperature sensor 20 disposed on the first end portion 10a.

As described above, the temperature measuring device 1 of one or more embodiments further includes the cold plate 50 having the inlet 51 and the outlet 52 for the coolant, and the plurality of heat sources 100 is disposed between the cold plate 50 and the heat pipe 10.

In this configuration, the heat source 100 can be mainly cooled through the cold plate 50, and additionally, the heat pipe 10 can be used as an auxiliary cooling device. Accordingly, it is possible to use the heat pipe 10 as an auxiliary cooling device even in a case where, for example, the heat source 100 generates more heat than the cooling capacity of the cold plate 50 and a thermal overload exceeding the cooling capacity of the cold plate 50 is applied. Accordingly, it is possible to measure the temperature changes of the plurality of heat sources 100 while improving the cooling capacity.

It should be noted that the technical scope of the present invention is not limited to the above-described embodiments or examples, and various modifications can be made without departing from the spirit of the present invention.

For example, in the first example, the heat source 100 is cooled through the cold plate 50, but the heat source 100 may be auxiliary cooled through the heat pipe 10.

In addition, in the third example, the heat source 100 is auxiliary cooled through the heat pipe 10. However, in a case where the auxiliary cooling of the heat source 100 is not necessary, the blowing of air from the fan F may be stopped or the amount of blown air may be adjusted.

In addition, in the first example, the side closer to the first end portion 10a of the heat pipe 10 is the condensation portion of the working fluid, and the temperature sensor 20 is disposed in the vicinity of the condensation portion, but a position of the temperature sensor 20 is not limited to the vicinity of the condensation portion. For example, as in the second example or the third example, the temperature sensor 20 may be disposed at an end portion opposite to the condensation portion in the longitudinal direction of the heat pipe 10. That is, as described in the first to third examples, the temperature sensor 20 may be disposed at a position where the temperature sensor 20 is able to detect the temperature changes of the plurality of heat sources 100 through the operation of circulating the working fluid.

In addition, during the period from the heat source 100 begins to operate and until circulation of the working fluid of the heat pipe 10 reaches a steady state, the temperatures measured by the temperature sensor 20 may vary due to the heat transfer and the cooling capacity of the heat pipe 10. In addition, the operation of the heat source 100 may be commanded by a device having the heat source 100, resulting in a state where the heat source 100 generates a greater amount of heat. That is, the temperature of the heat source 100 may change depending on an operation status of the heat source 100 instead of an abnormality in the heat source 100. In such a case, a threshold value of the temperature change ΔT may be set to be changed in advance in response to an operation command of the heat source 100 so that the determination unit does not determine that an abnormality has occurred.

In addition, it is possible to appropriately replace the constituent elements in the above-described embodiments with well-known constituent elements without departing from the scope of the present invention, and the above-described embodiments and modification examples may be appropriately combined. Although the disclosure has been described with respect to only a limited number of embodiments, those skilled in the art, having benefit of this disclosure, will appreciate that various other embodiments may be devised without departing from the scope of the present invention. Accordingly, the scope of the invention should be limited only by the attached claims.

### REFERENCE SIGNS LIST

1: Temperature measuring device
10: Heat pipe
10a: First end portion
10b: Second end portion
10c: First surface
10d: Second surface
10e: Side surface
11: Internal space
12: Wick
13: Container
20: Temperature sensor
30: Wire portion
41: Interface spreader plate
42: Insulating layer
43: Height adjustment layer
50: Cold plate
51: Inlet
52: Outlet
60: Heat sink
61: Fin
100: Heat source
F: Fan

1. A temperature measuring device comprising:
a heat pipe including a container that contains a working fluid;
a temperature sensor that detects a temperature of the heat pipe; and
a wire connected to the temperature sensor, wherein
the heat pipe receives heat from heat sources.

2. The temperature measuring device according to claim 1, further comprising:
an interface spreader plate disposed between the heat sources and the heat pipe, wherein
the heat pipe has a flat shape, and
the interface spreader plate extends in a direction orthogonal to a thickness direction of the heat pipe.

3. The temperature measuring device according to claim 1, further comprising:
an insulating layer disposed between the heat sources and the heat pipe, wherein
the heat pipe has a flat shape, and
the insulating layer has a plate shape extending in a direction orthogonal to a thickness direction of the heat pipe.

4. The temperature measuring device according to claim 1, further comprising:
a height adjustment layer disposed between the heat sources and the heat pipe, wherein
the heat pipe has a flat shape, and
the height adjustment layer has a plate shape extending in a direction orthogonal to a thickness direction of the heat pipe.

5. The temperature measuring device according to claim 1, wherein the wire is a flexible printed circuit (FPC).

6. The temperature measuring device according to claim 1, wherein
the temperature sensor is disposed at an end portion of the heat pipe in a longitudinal direction of the heat pipe, and
vapor of the working fluid condenses at the end portion.

7. The temperature measuring device according to claim 1, further comprising:
a heat sink disposed at an end portion of the heat pipe in a longitudinal direction of the heat pipe.

8. The temperature measuring device according to claim 1, further comprising:
a cold plate including an inlet for a coolant and an outlet for the coolant, wherein
the heat sources are disposed between the cold plate and the heat pipe.
